(19) United States
(12) Patent Application Publication
(10) Pub. No.: US 2026/0287525 A1
(43) Pub. Date: Sep. 24, 2026

(54) SEMICONDUCTOR INSPECTION APPARATUS AND INSPECTION METHOD

(71) Applicants: KABUSHIKI KAISHA TOSHIBA, Kawasaki-shi (JP); Toshiba Electronic Devices & Storage Corporation, Kawasaki-shi (JP)

(72) Inventors: Hirotoshi MURAYAMA, Yokohama (JP); Ryoichi OHARA, Himeji (JP); Reiko SAITO, Yokohama (JP); Katsuya EGUCHI, Yokohama (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/564,795

(22) Filed: Mar. 12, 2026

(30) Foreign Application Priority Data
Mar. 19, 2025 (JP) 2025-045766

(51) Int. Cl. G01N 23/18; G01N 21/88; G01N 21/95; H10P 74/20

(52) U.S. Cl. CPC G01N 23/18; G01N 21/8851; G01N 21/9501; H10P 74/203; G01N 2223/401; G01N 2223/41; G01N 2223/419; G01N 2223/423

(57) ABSTRACT

According to one embodiment, a semiconductor inspection apparatus includes processing circuitry. The processing circuitry acquires an image of a wafer by photographing the wafer with a photographing device. The processing circuitry detects, based on the image, a first coordinate point of a threading dislocation that has appeared on a back surface of the wafer and a second coordinate point of the threading dislocation that has appeared on a top surface of the wafer. The processing circuitry analyzes, based on the first coordinate point and the second coordinate point and a thickness of the wafer, an inclination of a dislocation line of the threading dislocation relative to a thickness direction of the wafer. The processing circuitry classifies the threading dislocation based on a result of the analyzing.

### CROSS-REFERENCE TO RELATED APPLICATION

This application is based upon and claims the benefit of priority from Japanese Patent Application No. 2025-045766, filed Mar. 19, 2025, the entire contents of which are incorporated herein by reference.

### FIELD

Embodiments described herein relate generally to a semiconductor inspection apparatus and an inspection method.

### BACKGROUND

In crystal growth of a semiconductor single-crystal ingot, a plurality of dislocation lines propagate at various inclinations in a substantially linear shape from a seed crystal side. Some of the dislocation lines are included in a wafer cut from the single-crystal ingot as various threading dislocations, such as threading screw dislocations (TSD) and threading mixed dislocations (TMD), which are a kind of threading screw dislocation. These types of threading dislocations are related to the quality of semiconductor devices formed on the wafer, and may cause adverse effects on the semiconductor devices. Accordingly, a distribution and a density of threading dislocations on a wafer are inspected by a semiconductor inspection apparatus prior to formation of semiconductor devices on the wafer.

The above-described semiconductor inspection apparatus is not particularly problematic; however, according to the present inventors' study, from the viewpoint of classifying threading dislocations whose dislocation lines are highly likely to cause adverse effects on semiconductor devices, it is desirable that inclinations of dislocation lines of threading dislocations be grasped. Example techniques of grasping the inclinations of dislocation lines include cross-sectional transmission electron microscopy (TEM) and multiphoton-excitation photoluminescence (MPPL). Cross-sectional TEM is a technique of allowing an electron beam to be made incident on a sample and investigating the electron beam that has passed through the sample, thereby obtaining a cross-sectional image of the sample. MPPL is a technique of allowing a pulse laser beam to be made incident on a sample to cause multi-photon excitation while controlling a position of focus, and investigating a fluorescence emitted from the sample to obtain fluorescent images deep inside the sample.

In both such techniques, however, since measurement is performed deep inside the sample, it is difficult to grasp inclinations of dislocation lines in a wafer over a wide range, due to the narrow range of measurement.

### BRIEF DESCRIPTION OF THE DRAWINGS

FIG. 1 is a block diagram showing a configuration example of a semiconductor inspection apparatus according to a first embodiment.

FIG. 2 is a schematic diagram showing an example of an ingot.

FIG. 3 is a schematic diagram showing an example of a wafer.

FIG. 4 is a schematic diagram for illustrating orientations of a wafer.

FIG. 5 is a block diagram showing a configuration example of a photographing device shown in FIG. 1.

FIG. 6 is a block diagram showing a configuration example of a computer shown in FIG. 1.

FIG. 7 is a block diagram showing a configuration example of a database shown in FIG. 1.

FIG. 8 is a flowchart for illustrating an example of an operation according to the first embodiment.

FIG. 9 is a schematic diagram for illustrating an example of an operation according to the first embodiment.

FIG. 10 is a schematic diagram for illustrating an example of an operation according to the first embodiment.

FIG. 11 is a schematic diagram for illustrating an example of an operation according to the first embodiment.

FIG. 12 is a schematic diagram for illustrating an example of an operation according to the first embodiment.

FIG. 13 is a schematic diagram for illustrating an example of an operation according to the first embodiment.

FIG. 14 is a block diagram showing a configuration of a photographing device according to a first modification of the first embodiment.

FIG. 15 is a block diagram showing a configuration of a photographing device according to a second modification of the first embodiment.

FIG. 16A is a block diagram showing a configuration example of a photographing device included in the semiconductor inspection apparatus according to the second embodiment.

FIG. 16B is a block diagram showing another configuration example of a photographing device included in the semiconductor inspection apparatus according to the second embodiment.

FIG. 17 is a schematic diagram for illustrating an example of an operation according to the second embodiment.

FIG. 18 is a schematic diagram for illustrating an example of an operation according to the second embodiment.

FIG. 19 is a schematic diagram for illustrating a first modification of the operation according to the second embodiment.

FIG. 20 is a schematic diagram for illustrating a second modification of the operation according to the second embodiment.

FIG. 21 is a schematic diagram for illustrating a second modification of the operation according to the second embodiment.

FIG. 22 is a schematic diagram for illustrating a third modification of the operation according to the second embodiment.

FIG. 23 is a schematic diagram for illustrating a fourth modification of the operation according to the second embodiment.

FIG. 24 is a schematic diagram for illustrating a fifth modification of the operation according to the second embodiment.

### DETAILED DESCRIPTION

In general, according to one embodiment, a semiconductor inspection apparatus includes processing circuitry. The processing circuitry is configured to acquire an image of a wafer by photographing the wafer with a photographing device. The processing circuitry is configured to detect, based on the image, a first coordinate point of a threading dislocation that has appeared on a back surface of the wafer and a second coordinate point of the threading dislocation that has appeared on a top surface of the wafer. The processing circuitry is configured to analyze, based on the first coordinate point and the second coordinate point and a thickness of the wafer, an inclination of a dislocation line of the threading dislocation relative to a thickness direction of the wafer. The processing circuitry is configured to classify the threading dislocation based on a result of the analyzing.

Hereinafter, embodiments will be described by way of examples with reference to the accompanying drawings. In the description that follows, elements having the same function and configuration will be assigned the same reference numeral. Also, in the embodiments to be described below, constituent elements (e.g., photographing devices, wafers, etc.) that are assigned reference numerals with a number or letter at the end for distinction will be referred to by the notation (reference numeral) without the number or letter at the end if they need not be distinguished from each other.

### First Embodiment

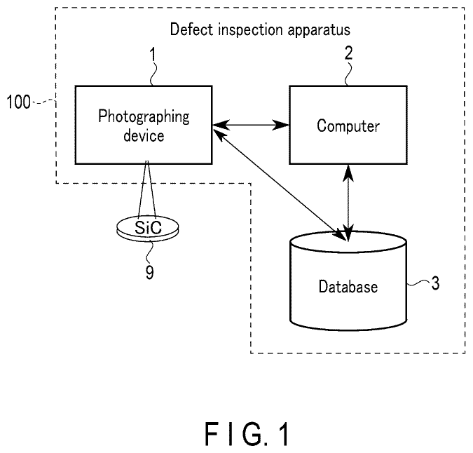

FIG. 1 is a block diagram showing a configuration example of a semiconductor inspection apparatus according to a first embodiment. The semiconductor inspection apparatus 100 includes a photographing device 1, a computer 2, and a database 3.

The photographing device 1 is adapted to photograph a wafer 9 to be subjected to a non-destructive inspection, and to generate images of the wafer 9. The wafer 9 is a semiconductor wafer acquired from a semiconductor single-crystal ingot, and is, for example, a silicon carbide (SiC) wafer that permits transmission of visible light. However, the wafer 9 may be a gallium nitride (GaN) or diamond (C) wafer. Moreover, the wafer 9 may be a silicon (Si) wafer.

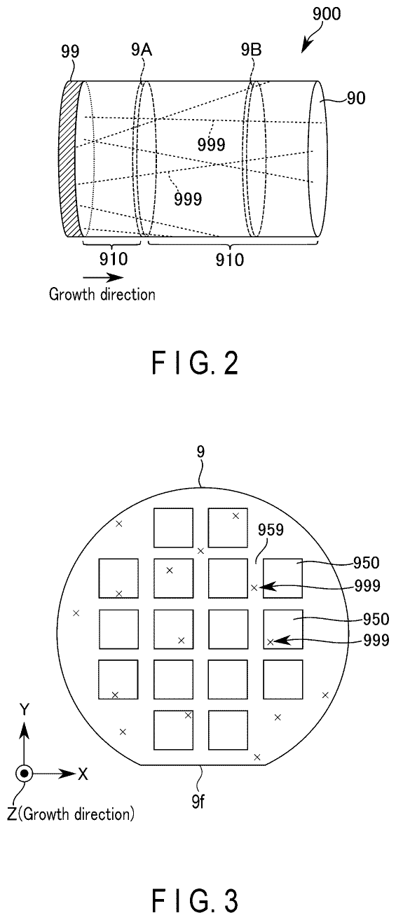

The wafer 9 and the ingot will be described in advance with reference to FIGS. 2 to 4. An ingot 900 shown in FIG. 2 is formed by growing a semiconductor crystal 90 on a seed crystal 99. The ingot 900 includes a plurality of threading dislocations 999. The threading dislocations 999 in the ingot 900 are derived from defects in the seed crystal 99. As the semiconductor crystal 90 grows, the threading dislocations 999 extend in a substantially linear manner from the side of the seed crystal 99 toward a growth end of the ingot 900 at a certain angle relative to the surface of the seed crystal 99, in accordance with a magnitude of a diameter of the ingot 900 (a diameter of the wafer). Through slicing of the ingot 900, a plurality of wafers 9 (9A and 9B) are cut from the ingot 900.

The wafer 9 is assigned with, for example, an identification number corresponding to a distance from the seed crystal 99 to determine a position of the wafer 9 in the ingot 900. For example, the wafer 9A is assigned an identification number ID<m>, and the wafer 9B is assigned an identification number ID<n>. Here, m and n are integers equal to or greater than 1. However, m has a value different from n.

The wafer 9A with the identification number ID<m> is used as a target for inspection of threading dislocations 999 in the wafer. Note that, in the ingot 900 from which a plurality of wafers 9 are cut, wafers other than the wafer 9A with an identification number Id<m> may not be photographed by the photographing device 1. A portion other than a position corresponding to the identification number ID<m> in the ingot 900 will be referred to as a “non-inspected region 910”. The wafer 9 cut from the non-inspected region 910 is excluded from the target of photographing by the photographing device 1.

FIG. 3 is a schematic diagram for illustrating the wafer 9. In FIG. 3, a top view (X-Y plane) of the wafer 9 as viewed from a growth direction (Z-direction) of the ingot (wafer) is shown. The wafer 9 may be either a bulk wafer (semiconductor substrate) cut from the ingot 900 and polished, or an epitaxial wafer formed on a bulk wafer by epitaxial growth of a semiconductor layer that is to be a part of a semiconductor device. In FIG. 3, chip areas 950, which are based on chip layout information, and an OF 9f, which indicates a predetermined orientation, are shown virtually. OF is an abbreviation for “orientation flat”. The wafer 9 includes a plurality of chip areas 950. A dicing area 959 is provided in the wafer 9 so as to surround the chip areas 950. By dicing the wafer 9 along the dicing area 959, the chip areas 950 are independently formed as individual semiconductor chips (semiconductor devices). Note that threading dislocations 999 immediately below or in the vicinity of an active region in which one or more semiconductor devices (e.g., MOSFETs, IGBTs, etc.) are formed in the chip area 950 have a high risk of causing malfunctions of semiconductor devices. On the other hand, threading dislocations 999 in a region that does not contribute to the characteristics of power devices (e.g., an element isolation region or the dicing area 959) in the wafer 9 have a low risk of causing malfunctions of the semiconductor devices.

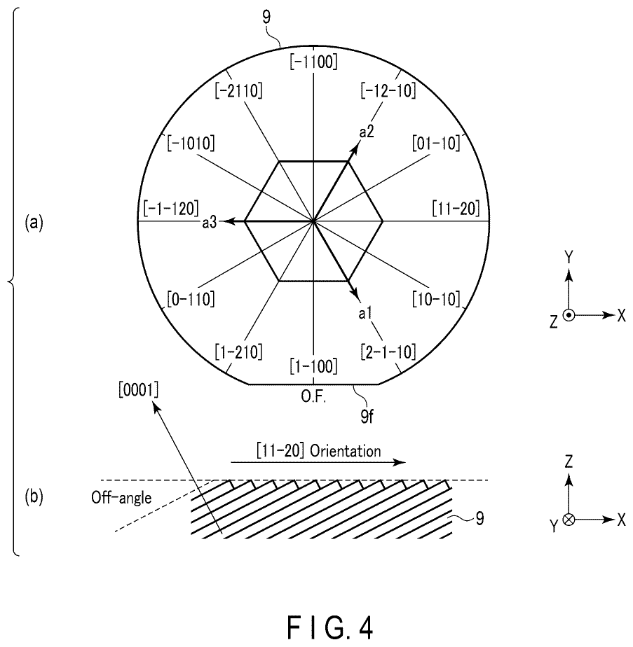

FIG. 4 is a schematic diagram for illustrating orientations of the wafer 9. In FIG. 4(a), a top view (X-Y plane) of the wafer 9 as viewed from a growth orientation (Z-direction) is shown, similarly to FIG. 3. It is assumed that, in the SiC wafer 9, an X-direction orientation perpendicular to the Z-direction is “[11-20]”, and a Y-direction orientation perpendicular to the Z-direction and the X-direction is “[−1100]”. In this case, an angle relative to the X-direction on the X-Y plane and an orientation in the wafer 9 can be denoted in association with each other. For example, an angle θ° relative to the X-direction on the X-Y plane can be denoted as the [11-20] orientation. Note that, in FIG. 4, the “-” symbol in the [11-20] orientation indicates a bar appended above the number “2” immediately after “-”. The same applies to the notations of the other orientations.

Also, an angle 30° relative to the X-direction on the X-Y plane can be denoted as an [01-10] orientation. Similarly, the angles 60°, 90°, 120°, 150°, 180°, 210°, 240°, 270°, 300°, and 330° relative to the X-direction on the X-Y plane can be respectively denoted as “[−12-10] orientation”, “[−1100] orientation”, “[−2110] orientation”, “[−1010] orientation”, “[−1-120] orientation”, “[0-110] orientation”, “[1-210] orientation”, “[1-100] orientation”, “[2-1-10] orientation”, and “[10-10] orientation”. The [1-100] orientation, corresponding to the angle 270°, is an orientation indicated by the OF 9f. Also, the angle 360° can be denoted as the “[11-20] orientation”, similarly to the angle 0°. Such angles and orientations can be suitably converted by associating them in advance and setting the associations in the storage 24.

The [2-1-10] orientation, corresponding to the angle 300°, may be referred to as an “a1-axis direction”. Similarly, the [−12-10] orientation, corresponding to the angle 60°, may be referred to as an “a2-axis direction”. The [−1-120] orientation, corresponding to the angle 180°, may be referred to as an “a3-axis direction”. The a1-axis, the a2-axis, and the a3-axis intersect at an angle of 120° on an identical plane. In addition thereto, there is a c-axis, not illustrated, orthogonal to an intersection of the a1-axis, the a2-axis, and the a3-axis. The a1-axis, the a2-axis, and the a3-axis, and the hexagonal shape denoted in FIG. 4(a) are in correspondence with the hexagonal crystal family to which SiC crystals belong.

In FIG. 4(b), an [0001] orientation is an orientation inclined by an off-angle toward an opposite side to the [11-20] orientation from the Z-direction. Since the off-angle has a magnitude of approximately 4°, the [0001] orientation is substantially an orientation along the Z-direction. The description of the wafer 9 and the ingot 900 has been completed.

Referring back to FIG. 1, the description continues from where the computer 2 executes various calculation processes based on the photographed images of the wafer 9. The computer 2 uses various types of information in the database 3 to inspect the wafer 9 based on the images of the wafer 9. The computer 2 is adapted to be able to control the photographing device 1 and the database 3.

The database 3 is adapted to store various types of information. The database 3 is adapted to be able to store, for example, information related to photographing by the photographing device 1, and data related to calculating by the computer 2. The database 3 is accessed by the computer 2 for analyzing and calculating by the computer 2. The database 3 is, for example, an external storage of the computer 2. The database 3 may be provided by a server.

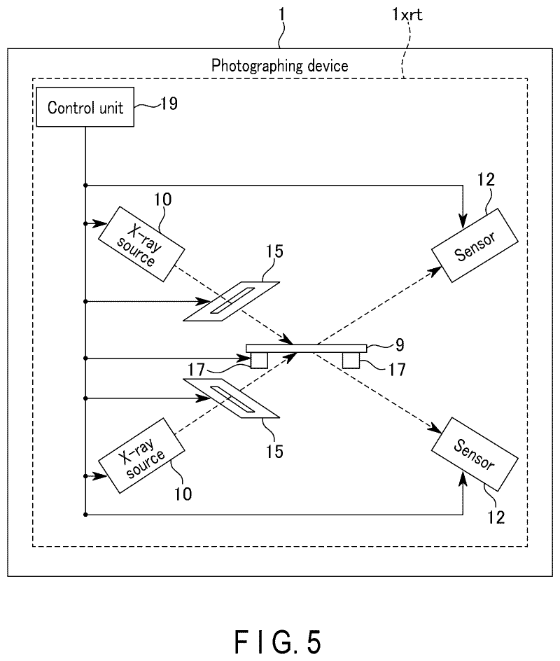

FIG. 5 is a schematic diagram showing a configuration example of the photographing device 1.

In the present embodiment, the photographing device 1 includes a reflection X-ray topography (XRT) device 1xrt. The X-ray topography device 1xrt includes two X-ray sources 10, two sensors 12, two slits 15, a vacuum chuck 17, and a control unit 19. One of the two X-ray sources 10, one of the two sensors 12, and one of the two slits 15 provided above the wafer 9 are mechanisms for performing reflection X-ray topography measurement on a top surface of the wafer 9. The other X-ray source 10, the other sensor 12, and the other slit 15 provided below the wafer 9 are mechanisms for performing reflective X-ray topography measurement on a back surface of the wafer 9.

The wafer 9 is mounted on the vacuum chuck 17, and is fixed by the vacuum chuck 17 by suction and held therein. The vacuum chuck 17 is adapted to continuously hold the wafer 9 under the control of the control unit 19, until photographing of the top and back surfaces of the wafer 9 is completed.

Each of the two slits 15 is provided between the corresponding one of the two X-ray sources 10 and the vacuum chuck 17. Each of the slits 15 allows the X-rays from each of the X-ray sources 10 to be focused into a sheet shape.

Each of the two X-ray sources 10 is adapted to irradiate the X-rays onto the wafer 9 on the vacuum chuck 17 through the corresponding slit 15. The X-rays are made incident on the wafer 9 at the Bragg's diffraction angle. The X-rays are diffracted in the wafer 9 to satisfy the Bragg's diffraction condition.

Each of the two sensors 12 is adapted to detect the diffracted X-rays from the wafer 9. An X-ray CCD camera, for example, is used as each of the sensors 12. A CCD is an abbreviation for a “charge-coupled device”.

The control unit 19 is adapted to control the two X-ray sources 10, the two sensors 12, the two slits 15, and the vacuum chuck 17, under the control of the computer 2. The control unit 19 is adapted to scan an entire region or a representative partial region of the wafer 9 through control of each unit. The control unit 19 is adapted to generate, based on an output from the sensor 12 related to a scanned back-surface region of the wafer 9, an X-ray topography image of the back surface of the wafer 9. The control unit 19 is also adapted to generate, based on an output from the sensor 12 related to a scanned top-surface region of the wafer 9, an X-ray topography image of the top surface of the wafer 9. The X-ray topography image indicates a result of inspecting of defects on the X-ray reflection surfaces (top and back surfaces) of the wafer 9. The X-ray topography image may be generated by the computer 2 which has received a result of the detecting from the photographing device 1.

The photographing device 1 is adapted to detect threading dislocations 999 included in the SiC wafer 9 based on the X-ray topography image. The threading dislocations 999 include various defects such as threading screw dislocations (TSD) and threading mixed dislocations (TMD). The threading mixed dislocations are dislocations in which the threading screw dislocations (TSD) and other dislocations are mixed. Examples of other dislocations include threading edge dislocations (TED) and basal plane dislocations (BPD).

Note that the photographing device 1 may be adapted to photograph the wafer 9 through destructive inspection, as long as defects (e.g., threading dislocations) of the wafer 9 can be detected. The photographing device 1 may be adapted, for example, to photograph the wafer 9 using the etch pit method, in which the wafer 9 is subjected to etching prior to photographing. Alternatively, the photographing device 1 may be adapted to photograph the wafer 9 using an optical microscope, in place of the X-ray topography device 1xrt, in addition to the etch pit method.

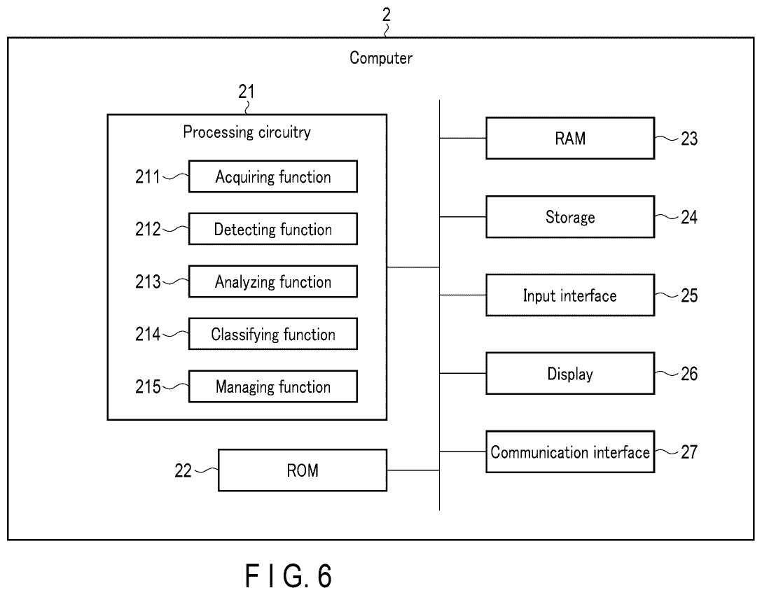

FIG. 6 is a block diagram showing a configuration example of the computer 2 of the semiconductor inspection apparatus 100. The computer 2 includes processing circuitry 21, a read-only memory (ROM) 22, a random-access memory (RAM) 23, a storage 24, an input interface 25, a display 26, and a communication interface 27.

The processing circuitry 21 is a processor adapted to be able to execute various programs (software and applications). The processing circuitry 21 is adapted to execute calculation processes using various types of information, various types of data, various types of signals, and various types of parameters. The processing circuitry 21 is adapted to control operations of the ROM 22, the RAM 23, the storage 24, the input interface 25, the display 26, and the communication interface 27. The processing circuitry 21 includes, for example, a central processing unit (CPU) and a graphics processing unit (GPU). Through execution of the programs, the processing circuitry 21 is adapted to execute, for example, processes of various functions such as an acquiring function 211, a detecting function 212, an analyzing function 213, a classifying function 214, and a managing function 215. The above-mentioned dividing of the processes among the functions is merely an example, and may be suitably changed. For example, the classifying function 214 may be included in the analyzing function 213 or the managing function 215, either partially or entirely. That is, since the processes of the respective functions are still executed by the processing circuitry 21, the dividing among the functions may be suitably changed.

The acquiring function 211 is adapted to acquire images of the wafer 9 by photographing the wafer 9 with the photographing device 1. The images of the wafer 9 include an X-ray topography image of the back surface of the wafer 9 and an X-ray topography image of the top surface of the wafer 9. The acquiring function 211 may be adapted to acquire a back-surface image and a top-surface image by photographing each of the back surface and the top surface of the wafer 9, with the wafer 9 being continuously held by the photographing device 1. The photographing device 1 and the acquiring function 211 are examples of an acquiring unit. Herein, the acquiring unit includes an X-ray topography device 1xrt adapted to photograph the wafer 9, thus allowing the acquiring function 211 to acquire images of the wafer 9. Moreover, the acquiring function 211 may be adapted to suitably store the acquired images of the wafer 9 in a memory such as the RAM 23 or the storage 24, or in the database 3.

The detecting function 212 is adapted to detect, based on the images acquired by the acquiring function 211, a first coordinate point of a threading dislocation that has appeared on the back surface of the wafer 9, and a second coordinate point of the threading dislocation that has appeared on the top surface of the wafer 9. The detecting function 212 may be adapted to detect the first coordinate point based on a top-surface image of the wafer 9, or may be adapted to detect the second coordinate point based on a back-surface image of the wafer 9.

The detecting function 212 is an example of a detecting unit.

The analyzing function 213 is adapted to analyze an inclination of a dislocation line of the threading dislocation 999 relative to a thickness direction of the wafer 9, based on the first coordinate point and the second coordinate point detected by the detecting function 212 and a thickness of the wafer 9. The analyzing function 213 may be adapted to further analyze an extension orientation of the dislocation line based on the first coordinate point and the second coordinate point. The analyzing function 213 may be adapted to predict, based on the first coordinate point and the second coordinate point and the extension orientation of the dislocation line, a third coordinate point of the threading dislocation 999 that would appear on a back surface of another wafer 9 different from said wafer 9 and cut from the same ingot 900 as the ingot 900 from which said wafer 9 has been cut, and a fourth coordinate point of the threading dislocation 999 that would appear on a top surface of said another wafer 9. The analyzing function 213 is an example of an analyzing unit.

The classifying function 214 is adapted to classify the threading dislocation 999 based on a result of the analyzing by the analyzing function 213. The classifying function 214 may be adapted to classify the threading dislocation according to whether or not an inclination indicated by the result of the analyzing falls within a threshold range. The classifying function 214 may be adapted to further classify the threading dislocation 999 according to which of a plurality of orientation ranges an extension orientation indicated by the result of the analyzing falls into. The classifying function 214 may be adapted to classify, based on the images of the wafer 9, whether or not the threading dislocation 999 is a threading mixed dislocation, and to further classify the threading dislocation 999 by combining the classifying result indicating the threading mixed dislocation and the classifying result based on the result of the analyzing. The classifying function 214 may be adapted to determine an abnormal area in the wafer 9 based on results of classifying of a plurality of threading dislocations 999 in the wafer 9. The classifying function 214 may be adapted to classify the threading dislocation 999 including the third coordinate point and the fourth coordinate point in accordance with a result of classifying of the threading dislocation 999 including the first coordinate point and the second coordinate point. The classifying function 214 is an example of a classifying unit.

The managing function 215 is adapted to manage information related to the wafer 9 by storing, in the database 3, information related to threading dislocations 999, such as results of detecting by the detecting function 212, results of analyzing by the analyzing function 213, and results of classifying by the classifying function 214. Moreover, the managing function 215 may be adapted to manage a distribution, a density, etc., of threading dislocations 999 on the wafer 9 through statistical processing of information related to the threading dislocations 999 in the database 3.

The ROM 22 is a non-volatile semiconductor memory. The ROM 22 is adapted to store programs and control data for controlling the computer 2.

The RAM 23 is a volatile semiconductor memory. The RAM 23 is used as a work area by the processing circuitry 21. The RAM 23 is adapted to temporarily store various types of data and parameters used in processing by the processing circuitry 21.

The storage 24 is a non-volatile storage device such as a hard disc drive (HDD), a solid-state drive (SSD), or a memory card. The storage 24 is adapted to store various types of information, various types of data, and various types of parameters. The storage 24 includes a database configured of a set of data items of a certain type. The programs and the control data may be stored in the storage 24. For example, the storage 24 is adapted to store a program PG related to an inspection method that is executed by the semiconductor inspection apparatus 100. Herein, the inspection method includes, for example: acquiring images of the wafer 9 by photographing the wafer 9; detecting, based on the images, a first coordinate point of a threading dislocation 999 that has appeared on a back surface of the wafer 9, and a second coordinate point of the threading dislocation 999 that has appeared on a top surface of the wafer 9; analyzing an inclination of a dislocation line of the threading dislocation 999 relative to a thickness direction of the wafer 9 based on the first coordinate point and the second coordinate point and a thickness of the wafer 9; and classifying the threading dislocation 999 based on a result of the analyzing. The program PG may be stored in the ROM 22. In either case, the program PG is stored in a non-transitory computer-readable storage medium.

The input interface 25 is adapted to accept an input of various types of operations from the user. As the input interface 25, a keyboard, a mouse, various types of switches, a touchpad, a touch panel display, and the like can be employed. An electric signal (hereinafter, an “operation signal”) corresponding to the input of the accepted operation is supplied to the processing circuitry 21.

The display 26 is adapted to display various types of data, such as the images of the wafer 9, under the control of the processing circuitry 21. As the display 26, a cathode ray tube (CRT) display, a liquid crystal display, an organic electroluminescent (EL) display, a light-emitting diode (LED) display, a plasma display, or any other display can be suitably employed.

The communication interface 27 includes various types of connectors, various types of ports, signal processing circuitry, communication modules, and the like. The communication interface 27 is adapted to connect the computer 2 to the photographing device 1 and the database 3. The communication interface 27 is adapted to send the control signal from the processing circuitry 21 to the photographing device 1 and the database 3. The communication interface 27 is adapted to send information (e.g., the images of the wafer 9) from the photographing device 1 and the information from the database 3 to the processing circuitry 21.

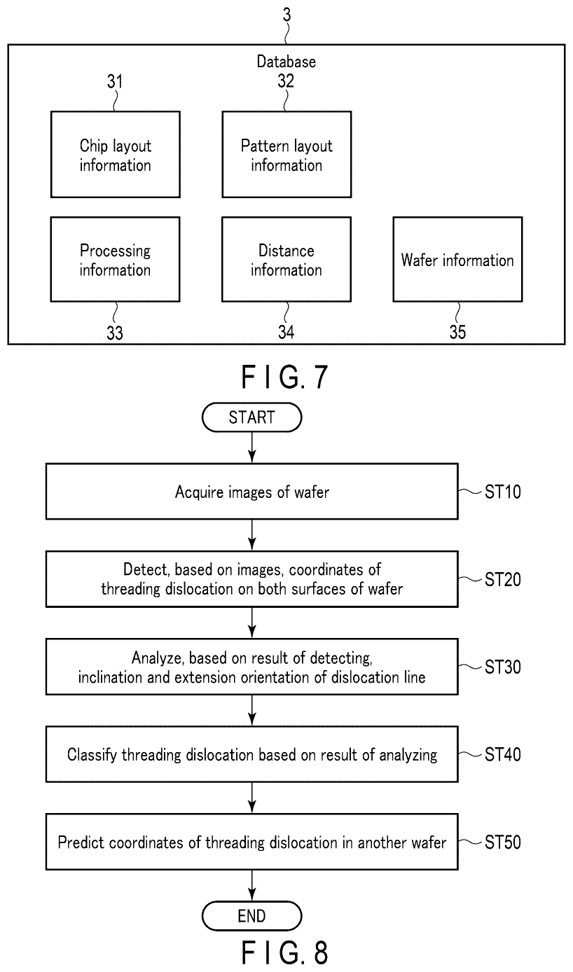

FIG. 7 is a diagram showing a configuration example of the database 3 of the semiconductor inspection apparatus 100. The database 3 includes chip layout information 31, pattern layout information 32, processing information 33, distance information 34, and wafer information 35.

The chip layout information 31 is information related to a layout of chip areas in the wafer 9. The chip areas are regions arranged in the wafer 9 for the chips singulated from the wafer 9 through dicing.

The pattern layout information 32 includes information related to a layout (coordinates) of various patterns arranged in the chip areas in the wafer 9. The pattern layout information 32 includes, for example, information related to a layout of active regions (e.g., a diffusion layer pattern or an impurity semiconductor region pattern), information related to a layout of a gate pattern, information related to a layout of a wiring pattern, and the like.

The processing information 33 includes information related to manufacturing processes such as ion implanting, film formation, and etching. The information on various manufacturing processes included in the processing information is associated with a layout of a pattern included in the pattern layout information.

The distance information 34 is information related to a distance from an end portion on the seed crystal side of the ingot to the target wafer 9 in a growth surface orientation of the ingot. For example, the distance from an end portion of the ingot to the target wafer 9 is determined based on the thickness of the wafer 9 and the position of the wafer 9 in the ingot.

The wafer information 35 includes an ingot number, an identification number of the wafer 9, back-surface dislocation coordinates, top-surface dislocation coordinates, an inclination of the dislocation line, an extension orientation of the dislocation line, feature-by-feature grouping information, and a distribution and a density of killer TSD. The ingot number is a number identifying an ingot from which the wafer 9 has been cut. The identification number of the wafer 9 is a number identifying each wafer 9 that has been cut from the ingot. The back-surface dislocation coordinates are coordinates (a first coordinate point) indicating a position of a threading dislocation that has appeared on a back surface of the wafer 9. The top-surface dislocation coordinates are coordinates (a second coordinate point) indicating a position of the threading dislocation that has appeared on a top surface of the wafer 9. The back surface of the wafer 9 refers to one of the both surfaces of the wafer 9 that faces the seed crystal side in the ingot. The top surface of the wafer 9 refers to a surface opposite to the back surface of the wafer 9, and has been formed by crystal growth after the formation of the back surface of the wafer 9. Accordingly, a threading dislocation in the wafer 9 is formed by being propagated in a substantially linear shape at various inclinations from the back surface of the wafer 9 toward the top surface. The inclination of the dislocation line is an inclination of the threading dislocation relative to the thickness direction of the wafer 9. The thickness direction of the wafer 9 is an orientation of crystal growth of the ingot, and refers to an orientation of a minimum distance connecting the same coordinate points on the back surface and the top surface of the wafer 9. The extension orientation of the dislocation line may be an orientation in which the dislocation line of the threading dislocation extends in the ingot, but is managed in the present embodiment as an orientation obtained by projecting, onto the top surface of the wafer 9, the orientation in which the dislocation line extends in the ingot. The feature-by-feature grouping information is information obtained by performing feature-by-feature grouping of the threading dislocations according to the specific patterns, such as a specific pattern indicating the magnitude of the inclination of the dislocation line and a specific pattern indicating an extension orientation. The killer TSD are threading screw dislocations (TSD) with a killer property that causes fatal adverse effects on semiconductor devices formed on the wafer 9. Examples of the fatal adverse effects include breakage or malfunctions caused by a current leakage. According to the present inventors'study, there is a tendency for a portion where a current leakage occurs to substantially match an inclination within a specific range relative to the thickness direction of the wafer 9. In other words, there is a tendency for a threading dislocation that has propagated at an inclination in the range from +θ1 to −θ2 from a direction perpendicular to the top and back surfaces of the wafer 9 to be related to the current leakage. Accordingly, from the viewpoint of specifying killer TSD, it is preferable, for example, to classify, among various threading dislocations, threading dislocations whose inclinations of dislocation lines fall within a specific threshold range. The distribution of the killer TSD is information indicating a certain region in the wafer 9 or the entire surface of the wafer 9 over which the killer TSD are distributed. The density of the killer TSD is a value indicating a density (cm\hat{ }-2) of the killer TSD (where “\hat{ }” is a symbol indicating an exponentiation), and is the number of killer TSD per 1 cm\hat{ }2 on the wafer 9. Note that the density of the killer TSD may be included in the distribution of the killer TSD. In this case, the distribution of the killer TSD is information showing a density of the killer TSD over a certain region or the entire surface of the wafer 9. Moreover, the distribution of the killer TSD may be combined with, for example, the chip layout information 31 and represented as mapping on the wafer 9, as shown in FIG. 3. The distribution and the density of the killer TSD are generated through statistical processing, by the managing function 215 of the processing circuitry 21, of information related to the number and coordinates of threading dislocations 999 indicating a specific pattern of killer TSD in the database 3.

Note that the database 3 may be stored in an internal storage 24 of the computer 2.

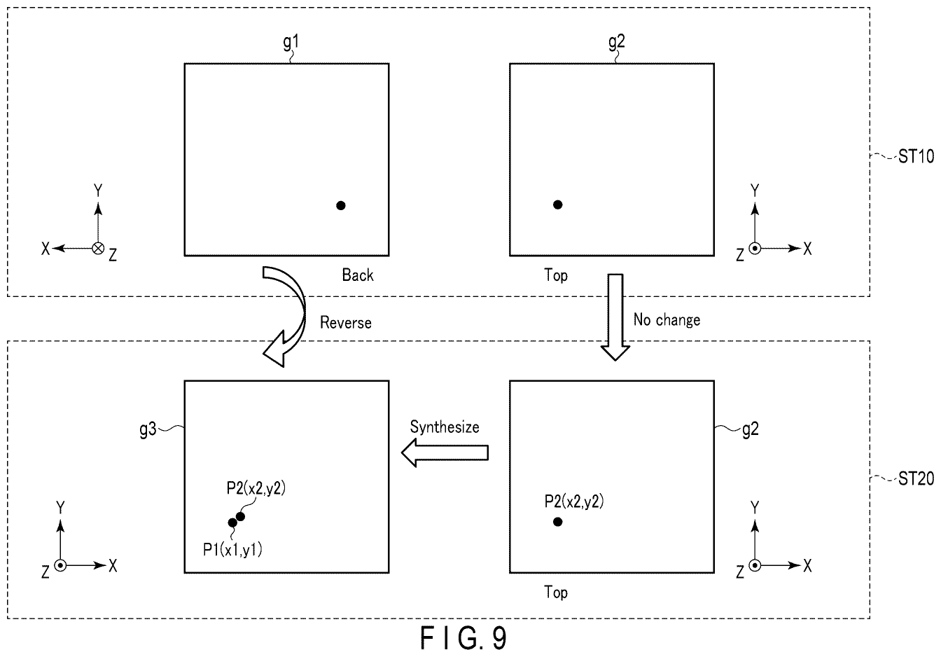

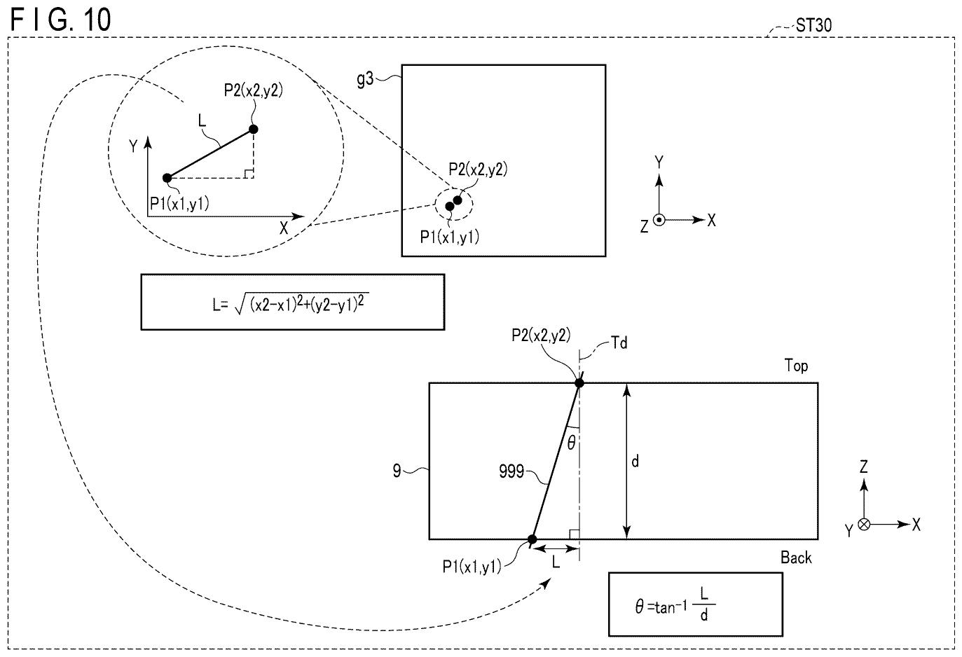

Next, an operation example of the semiconductor inspection apparatus 100 with the above-described configuration will be described using the flowchart of FIG. 8 and the schematic diagrams shown in FIGS. 9 to 13.

### (Step ST10)

Upon receiving a control signal for a computer, the photographing device 1 of the semiconductor inspection apparatus 100 starts photographing a wafer 9. The control unit 19 of the photographing device 1 scans an entire region or a representative partial region in the wafer 9 held by the vacuum chuck 17 through control of two X-ray sources 10, two sensors 12, and two slits 15. The vacuum chuck 17 continuously holds the wafer 9 until photographing of both the top and back surfaces of the wafer 9 is completed.

After the scanning, the control unit 19 generates, based on an output from the sensors 12 related to a scanned back-surface region of the wafer 9, an image g1 of the back surface of the wafer 9, as shown in FIG. 9. Also, the control unit 19 generates, based on an output from the sensors 12 related to a scanned top-surface region of the wafer 9, an image g2 of the top surface of the wafer 9. The control unit 19 transmits the generated images g1 and g2 to the computer 2. The processing circuitry 21 of the computer 2 acquires the images of the wafer 9. Note that, in an X-Y plane, the Y-coordinates are the same for corresponding points on the back-surface image g1 and the top-surface image g2, while the X-coordinates are negated.

### (Step ST20)

The processing circuitry 21 detects, based on the images g1 and g2 acquired at step ST10, coordinates of a threading dislocation 999 on both surfaces of the wafer 9. For example, the processing circuitry 21 aligns coordinate systems of the images g1 and g2 by reversing the back-surface image g1 across a Y-axis, which is along the Y-direction. Thereafter, the processing circuitry 21 detects, based on the image g1, a first coordinate point P1 (x1, y1) of a threading dislocation 999 that has appeared on a back surface of the wafer 9. Also, the processing circuitry 21 detects, based on the image g2, a second coordinate point P2 (x2, y2) of a threading dislocation 999 that has appeared on a top surface of the wafer 9. Thereafter, the processing circuitry 21 generates a synthesis image g3 obtained by synthesizing images g1 and g2 in the same coordinate system. Note that, since the processing of step ST30 and thereafter can be executed based on the first coordinate point and the second coordinate point, the synthesis image g3 is not required to be generated. For ease of understanding, the description will be made below with reference to the drawings illustrating the synthesis image g3. The processing circuitry 21 stores a result of the detecting at step ST20 as the wafer information 35 in the database 3.

### (Step ST30)

The processing circuitry 21 analyzes, based on the result of the detecting at step ST20, an inclination and an extension orientation of a dislocation line of the threading dislocation in the wafer 9. For example, the processing circuitry 21 calculates a length L between the first coordinate point P1 (x1, y1) and the second coordinate point P2 (x2, y2) in the X-Y plane of the wafer 9, as shown in the top part of FIG. 10 and the formula (1).

$$L = \{ ( x 2 - x 1 ) \hat{} 2 + ( y 2 - y 1 ) \hat{} 2 \} \hat{} ( 1 / 2 ) \qquad ( 1 )$$

The processing circuitry 21 calculates, based on the length L and a thickness d of the wafer 9, the inclination θ of the dislocation line of the threading dislocation 999 relative to a thickness direction Td of the wafer 9, as shown in the bottom part of FIG. 10 and the formula (2).

$$θ = tan \hat{} - 1 ( L / d ) \qquad ( 2 )$$

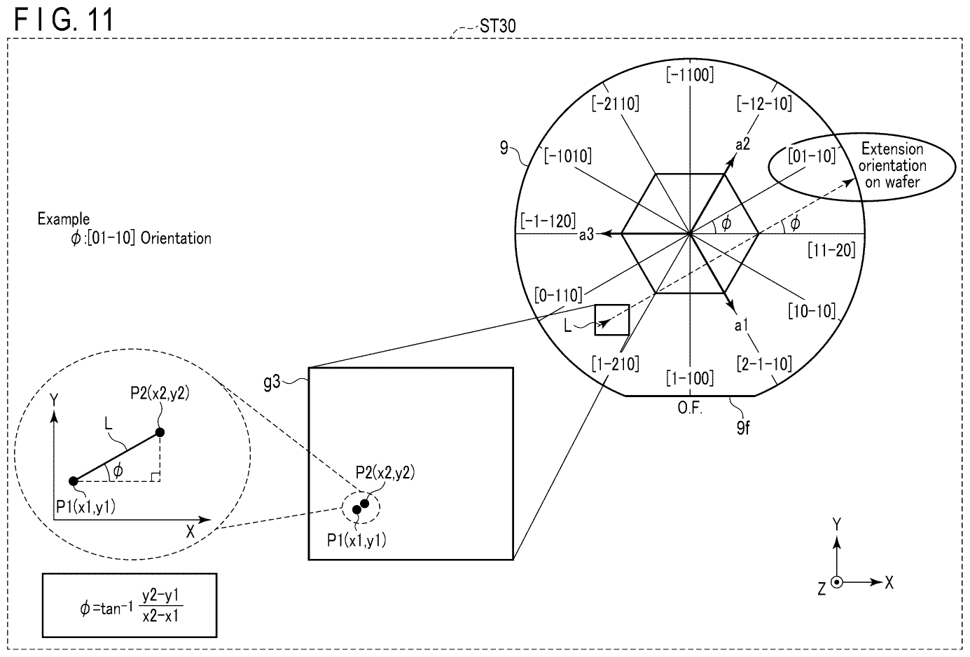

The processing circuitry 21 calculates, based on the first coordinate point P1 (x1, y1) and the second coordinate point P2 (x2, y2), an angle φ of the threading dislocation relative to the X-direction in the X-Y plane, as shown in FIG. 11 and the formula (3).

$$φ = tan \hat{} - 1 \{ ( y 2 - y 1 ) / ( x 2 - x 1 ) \} \qquad ( 3 )$$

The angle φ of the threading dislocation corresponds to the extension orientation of the threading dislocation, and can be denoted as, for example, the [01-10] orientation in the wafer 9. Thereby, the processing circuitry 21 analyzes the extension orientation of the threading dislocation 999 projected on the X-Y plane from the angle φ of the threading dislocation 999 projected on the X-Y plane. Note that the processing circuitry 21 may be adapted to analyze first either the inclination θ of the dislocation line or the extension orientation. Moreover, the analyzing of the extension orientation is not required to be executed, and may be omitted. The processing circuitry 21 stores a result of the analyzing at step ST30 as the wafer information 35 in the database 3.

### (Step ST40)

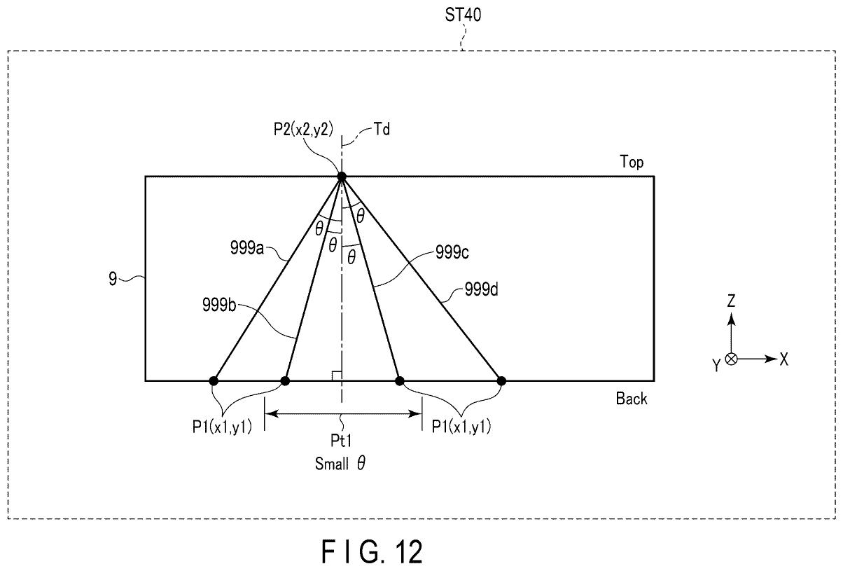

The processing circuitry 21 classifies the threading dislocation 999 in the wafer 9 based on a result of the analyzing at step ST30. For example, the processing circuitry 21 may be adapted to classify threading dislocations 999a to 999d according to whether or not the inclination θ indicated by the result of the analyzing falls within a threshold range, as shown in FIG. 12. In this case, the processing circuitry 21 classifies, among the threading dislocations 999a to 999d, threading dislocations 999b and 999c having a small inclination θ into a specific pattern Pt1. The processing circuitry 21 may or may not be adapted to classify the remaining threading dislocations 999a and 999d into another specific pattern.

Moreover, the processing circuitry 21 may be adapted to further classify the threading dislocations 999 according to which of the orientation ranges the extension orientation indicated by the result of the analyzing falls into. Furthermore, the processing circuitry 21 may be adapted to classify, based on the images of the wafer 9, whether or not the threading dislocation 999 is a threading mixed dislocation, and to further classify the threading dislocation 999 by combining a result of the classifying indicating the threading mixed dislocation and a result of the classifying based on the result of the analyzing. Moreover, the processing circuitry 21 may be adapted to determine an abnormal area in the wafer 9 based on results of classifying of a plurality of threading dislocations 999 in the wafer 9. The processing circuitry 21 stores the results of the classifying at step ST40 as the wafer information 35 in the database 3.

### (Step ST50)

The processing circuitry 21 predicts, based on the results at steps ST20 and ST30 in a certain wafer 9, coordinates of the threading dislocation 999 in another wafer 9. For example, the processing circuitry 21 predicts, based on the first coordinate point P1 (x1, y1) and the second coordinate point P2 (x2, y2) of the threading dislocation 999 in the certain wafer 9 and the extension orientation of the dislocation line of the threading dislocation 999, a third coordinate point P3 (x3, y3) of the threading dislocation 999 that would appear on a back surface of another wafer 9 and a fourth coordinate point P4 (x4, y4) of the threading dislocation 999 that would appear on a top surface of said another wafer 9.

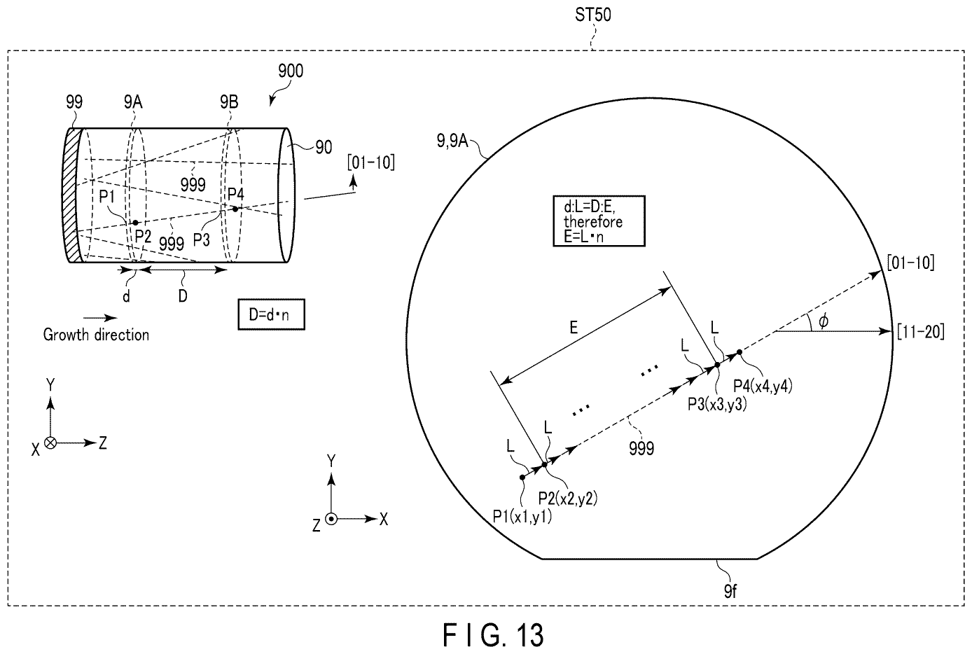

It is assumed, for example, that the certain wafer 9 is a wafer 9A and that said another wafer 9 is a wafer 9B, as shown at the left of FIG. 13. It is also assumed that, in the ingot 900, a distance D between a top surface of the wafer 9A and a back surface of said another wafer 9B is n times the thickness d of the wafer 9A.

On the other hand, if the wafer 9A has the thickness d, the length between the first coordinate point P1 (x1, y1) and the second coordinate point P2 (x2, y2) in the X-Y plane of the wafer 9A is L, as shown at the right of FIG. 13. That is, there is a relationship wherein the threading dislocation 999 is propagated by a length L if the wafer 9 has a thickness d. In accordance therewith, there is a relationship wherein the threading dislocation 999 is extended by a length E if the wafers 9A and 9B are at a distance D (=d•n). At this time, d: L=D: E, and therefore the length E of an extension is expressed by the formula (4):

$$E = L \cdot n \qquad ( 4 )$$

Here, the length E represents a length between the second coordinate point P2 (x2, y2) on the top surface of the wafer 9A and the third coordinate point P3 (x3, y3) on the back surface of the wafer 9B in the case where the threading dislocation 999 is extended along the extension orientation [01-10] on the wafer 9 or along the angle φ. That is, the third coordinate point P3 (x3, y3) on the back surface of said another wafer 9B is predicted to be a position obtained by extending the second coordinate point P2 (x2, y2) on the top surface of the certain wafer 9A by the length E along the extension orientation. Specifically, the third coordinate point P3 (x3, y3) may be derived by assuming, for example, x3=x2+E•cosφ and y3=y2+E•sinφ. Alternatively, from the viewpoint of reducing calculation errors related to the angle φ, the coordinates of the third coordinate point P3 (x3, y3) may be derived as shown in the formula (5):

$$x 3 = ( x 2 - x 1 ) \cdot n + x 2 \qquad ( 5 )$$

$$y 3 = ( y 2 - y 1 ) \cdot n + y 2$$

Also, the fourth coordinate point P4 (x4, y4) on the top surface of the wafer 9B is predicted to be a position obtained by extending the third coordinate point P3 (x3, y3) by a length L along the extension orientation. The coordinates of the fourth coordinate point P4 (x4, y4) may be derived as shown in the formula (6):

$$x 4 = ( x 2 - x 1 ) + x 3 \qquad ( 6 )$$

$$y 4 = ( y 2 - y 1 ) + y 3$$

Also, the processing circuitry 21 stores, as the wafer information 35 in the database 3, prediction results (the third coordinate point and the fourth coordinate point) at step ST50 in association with an identification number of said another wafer 9B. Note that the inclination and the extension orientation of the dislocation line related to the third coordinate point and the fourth coordinate point in said another wafer 9B are the same as those of the dislocation line related to the first coordinate point and the second coordinate point in the certain wafer 9A, and are thus not required to be analyzed. Accordingly, the processing circuitry 21 stores a result of analyzing related to said another wafer 9B as the wafer information 35 by copying a result of analyzing related to the certain wafer 9A. Thereafter, the processing circuitry 21 ends the processing.

According to the first embodiment described above, the processing circuitry 21 acquires images g1 and g2 of a wafer 9 by photographing the wafer 9 with the photographing device 1. The processing circuitry 21 detects, based on the images g1 and g2, a first coordinate point P1 (x1, y1) of a threading dislocation 999 that has appeared on a back surface of the wafer 9 and a second coordinate point P2 (x2, y2) of the threading dislocation 999 that has appeared on a top surface of the wafer 9. The processing circuitry 21 analyzes an inclination φ of a dislocation line of the threading dislocation 999 relative to a thickness direction Td of the wafer 9, based on the first coordinate point and the second coordinate point and a thickness d of the wafer 9. The processing circuitry 21 classifies the threading dislocation 999 based on a result of the analyzing. With the configuration of analyzing, based on images obtained by photographing a wafer, an inclination of a dislocation line from a first coordinate point of a threading dislocation that has appeared on a back surface of the wafer and a second coordinate point of the threading dislocation that has appeared on a top surface of the wafer, instead of measuring deep inside the sample, it is possible to grasp inclinations of dislocation lines in the wafer over a wide range.

Moreover, according to the first embodiment, the processing circuitry 21 may be adapted to classify the threading dislocation according to whether or not the inclination θ indicated by the result of the analyzing falls within a range of thresholds θ1 to θ2. In this case, threading dislocations whose inclinations θ fall within the threshold range can be classified into, for example, a specific pattern with a high killer property that causes fatal adverse effects on the semiconductor devices. Also, since threading dislocations can be classified according to whether or not they fall within the threshold range, it is possible to manage a distribution of specific threading dislocations with a high killer property, instead of a distribution of all the threading dislocations. It is thereby possible to improve the yield by employing such information to the quality evaluation, defect inspection, and the like during manufacturing of semiconductor devices. By discarding semiconductor devices that use a chip area in which a threading dislocation with a high killer property is located, it is possible to reduce the occurrence of malfunctioning semiconductor devices. This is applicable not only to results of classifying based on results of analyzing indicating an inclination θ that falls within a threshold range, but also to other results of analyzing that correspond to results of classifying of specific patterns with a high killer property.

Furthermore, according to the first embodiment, the processing circuitry 21 may be adapted to further analyze an extension orientation of the dislocation line based on the first coordinate point and the second coordinate point. In this case, threading dislocations can be classified according to the extension orientation of the dislocation line. Furthermore, the threading dislocations can be classified according to the combination of the inclination of the dislocation line and the extension orientation of the dislocation line.

Moreover, according to the first embodiment, the processing circuitry 21 may be adapted to further classify a threading dislocation according to which of a plurality of orientation ranges an extension orientation indicated by a result of analyzing falls into. In this case, the threading dislocations can be managed according to each of the orientation ranges.

Furthermore, according to the first embodiment, the processing circuitry 21 may be adapted to classify, based on images, whether or not the threading dislocation is a threading mixed dislocation, and to further classify the threading dislocation by combining a result of the classifying indicating the threading mixed dislocation and a result of classifying based on the result of the analyzing. In this case, by combining, for example, the result of the classifying indicating the threading mixed dislocation and a result of classifying indicating that the inclination of the dislocation line falls within the threshold range, it is possible to classify the threading dislocation into a specific pattern with an extremely high killer property.

Moreover, according to the first embodiment, the processing circuitry 21 may be adapted to determine an abnormal area in the wafer based on results of classifying of a plurality of threading dislocations in the wafer. In this case, a region in which the number of threading dislocations that have been classified into a pattern with a high killer property is greater than a threshold, for example, can be determined to be an abnormal area.

Furthermore, according to the first embodiment, the processing circuitry 21 may be adapted to predict, based on the first coordinate point and the second coordinate point and the extension orientation of the dislocation line, a third coordinate point of the threading dislocation that would appear on a back surface of another wafer 9B different from the wafer 9A, which has been cut from the same ingot 900 as the ingot 900 from which the wafer 9A has been cut, and a fourth coordinate point of the threading dislocation that would appear on a top surface of said another wafer 9B. In this case, by photographing and analyzing the prediction target wafer 9, it is possible to reduce the load, compared to the case of photographing and analyzing all the wafers 9. It is also possible to subject the wafer 9 to be photographed to destructive inspection, as well as non-destructive inspection. Moreover, the wafer 9A may not be only on a side closer to the seed crystal 99, but also on a side farther from the seed crystal 99. In this case, said another wafer 9B is on a side closer to the seed crystal 99. That is, it is possible to predict, based on the first coordinate point and the second coordinate point of the threading dislocation 999 in the wafer 9A on a side farther from the seed crystal 99, a third coordinate point and a fourth coordinate point of the threading dislocation 999 in said another wafer 9B on a side closer to the seed crystal 99. Moreover, based on the first coordinate point and the second coordinate point of the threading dislocation 999 in each of two wafers 9A and 9B cut at positions distanced from each other, a third coordinate point and a fourth coordinate point of the threading dislocation 999 in another wafer between the two wafers 9A and 9B may be predicted.

Furthermore, according to the first embodiment, the processing circuitry 21 may be adapted to a classify, in accordance with a result of classifying of the threading dislocation including the first coordinate point and the second coordinate point in a certain wafer 9A, a threading dislocation including the third coordinate point and the fourth coordinate point in another wafer 9B. In this case, the analyzing and the like of the inclination of the dislocation line and the extension orientation based on the third coordinate point and the fourth coordinate point can be omitted. That is, the inclination and the extension orientation of the threading dislocation including the predicted third coordinate point and fourth coordinate point are estimated to be substantially the same as those of the threading dislocation including the first coordinate point and the second coordinate point used for the prediction, from the property of the threading dislocation of propagating in a substantially linear shape. Thus, the analyzing of the inclination of the dislocation line and the extension orientation related to the predicted third coordinate point and fourth coordinate point is not required and can be omitted.

Furthermore, according to the first embodiment, the photographing device 1 photographs each of the back surface and the top surface of the wafer 9 while continuously holding the wafer 9, thus allowing the processing circuitry 21 to acquire a back-surface image and a top-surface image of the wafer 9. The processing circuitry 21 may be adapted to detect the first coordinate point based on the back-surface image and to detect the second coordinate point based on the top-surface image. In this case, since the wafer 9 is not released for re-holding during photographing of the wafer 9, it is possible to reduce a position gap between coordinate systems on the back-surface image and the top-surface image. In addition, by measuring both surfaces of the wafer by reflection XRT while fixing the wafer 9 by suction, it is possible to maintain coordinate precision required for calculating the inclination of the dislocation line. It can be expected, for example, that a position gap between the coordinate systems on the back-surface image and the top-surface image is equal to or lower than 10 μm, preferably equal to or lower than 1 μm. On the other hand, in the conventional reflection XRT, if a wafer that has been fixed by suction is unfixed after measurement of its top surface, conveyed and flipped back, and then fixed by suction again, and the top surface of the wafer is measured, the position gap between the coordinate systems becomes approximately 100 μm. That is, in the conventional reflection XRT, the position gap between the coordinate systems is large, thus making it difficult to maintain the coordinate precision required for calculating the inclination of the dislocation line.

Moreover, according to the first embodiment, the acquiring unit including the photographing device 1 and the acquiring function 211 may include an X-ray topography device 1xrt adapted to photograph a wafer 9, thereby acquiring images g1 and g2 of the wafer 9. In this case, it is possible to photograph and acquire images of a wafer using an X-ray topography device, among given photographing devices capable of photographing a wafer.

### First Modification of First Embodiment

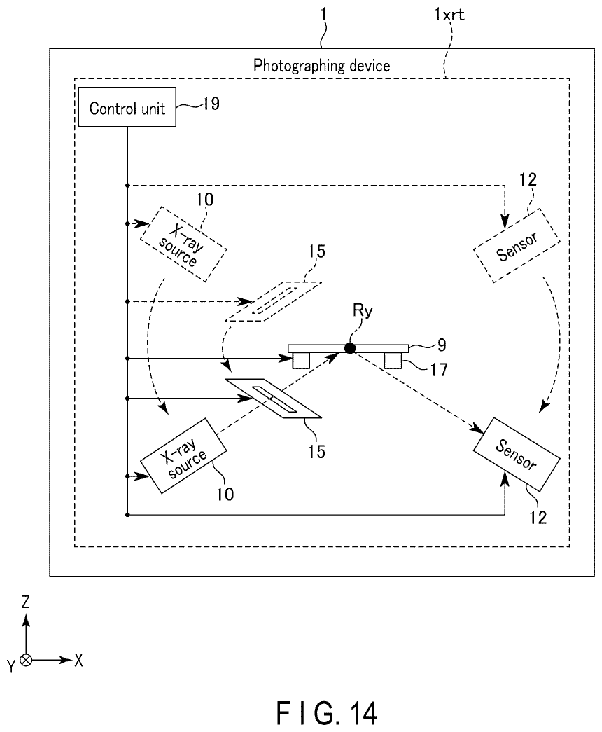

In the first embodiment, the X-ray topography device 1xrt includes two X-ray sources 10, two sensors 12, and two slits 15; however, the configuration is not limited thereto. For example, the X-ray topography device 1xrt may include a single X-ray source 10, a single sensor 12, and a single slit 15, as shown in FIG. 14. In this case, the control unit 19 may be adapted to switch between a first arrangement and a second arrangement via an unillustrated driving unit by, for example, pivoting the X-ray sources 10, the sensors 12, and the slits 15 around a rotation axis Ry, which is along the Y-direction in the wafer 9. Here, the first arrangement is an arrangement for allowing the X-ray source 10, the sensor 12, and the slit 15 positioned above the wafer 9 to perform reflection X-ray topography on the top surface of the wafer 9. The second arrangement is an arrangement for allowing the X-ray source 10, the sensor 12, and the slit 15 positioned below the wafer 9 to perform reflection X-ray topography on the back surface of the wafer 9. Also, the control unit 19 may be adapted to allow the vacuum chuck 17 to suitably ascend or descend in accordance with the switching of the arrangement. According to the first modification, since only a single X-ray source 10, a single sensor 12, and a single slit 15 are provided, it is possible to reduce the cost of the X-ray topography device 1xrt.

### Second Modification of First Embodiment

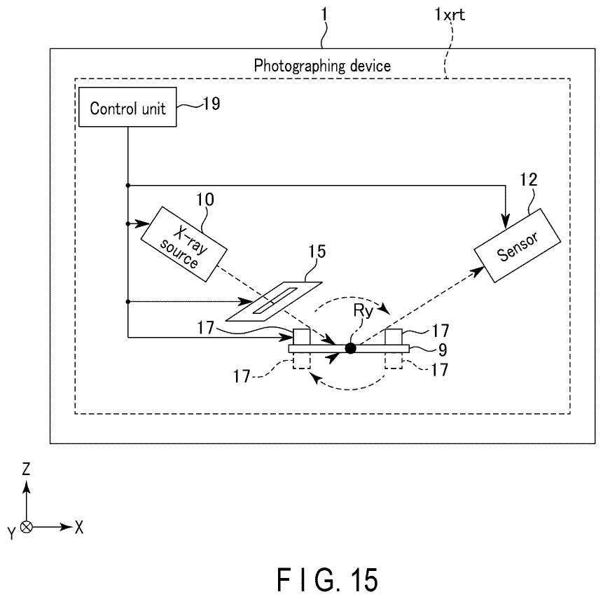

In the first embodiment, the X-ray topography device 1xrt includes two X-ray sources 10, two sensors 12, and two slits 15; however, the configuration is not limited thereto. For example, the X-ray topography device 1xrt may include a single X-ray source 10, a single sensor 12, and a single slit 15, as shown in FIG. 15. In this case, the control unit 19 may be adapted to switch between top-surface photographing and back-surface photographing of the wafer 9 via an unillustrated driving unit by, for example, reversing the vacuum chuck 17 around a rotation axis Ry, which is along the Y-direction in the wafer 9. Also, the control unit 19 may be adapted to allow the vacuum chuck 17 to suitably ascend or descend in accordance with the switching of the surface to be photographed. According to the second modification, since only a single X-ray source 10, a single sensor 12, and a single slit 15 are provided, it is possible to reduce the cost of the X-ray topography device 1xrt. In the second modification, a case has been assumed where the X-rays output from the single X-ray source 10 are radiation rays; however, the configuration is not limited thereto. For example, the X-rays output from the single X-ray source 10 may be synchrotron radiation. In this case, it is possible to suitably use, for example, a large-scale synchrotron radiation facility called SPring-8 as the X-ray topography device 1xrt. In accordance therewith, the acquiring function 211 does not include the photographing device 1, and is implemented as a function of the processing circuitry 21 adapted to execute processing of reading, from a RAM 23 or a storage 24 storing an image obtained by photographing a wafer 9, the image. Even with such a modification, it is possible to obtain similar effects as can be obtained by the first embodiment. The configuration in which the acquiring function 211 does not include the photographing device 1 may be applied to the first embodiment and its first modification, as well as the embodiments to be described below and their modifications.

### Second Embodiment

Next, a semiconductor inspection apparatus according to a second embodiment will be described.

The second embodiment is a variant in terms of the images of the wafer and the photographing device, in which a wafer 9 with etch pits formed on its surface by the etch pit method is photographed with an optical microscopy device.

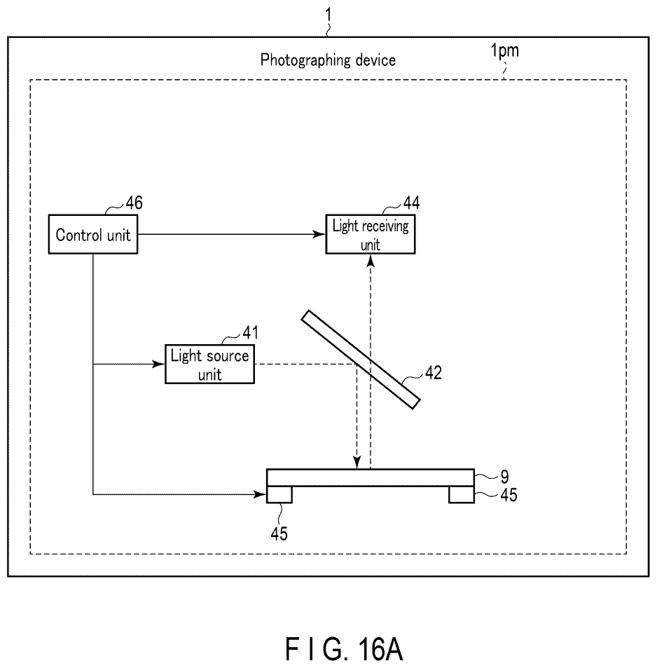

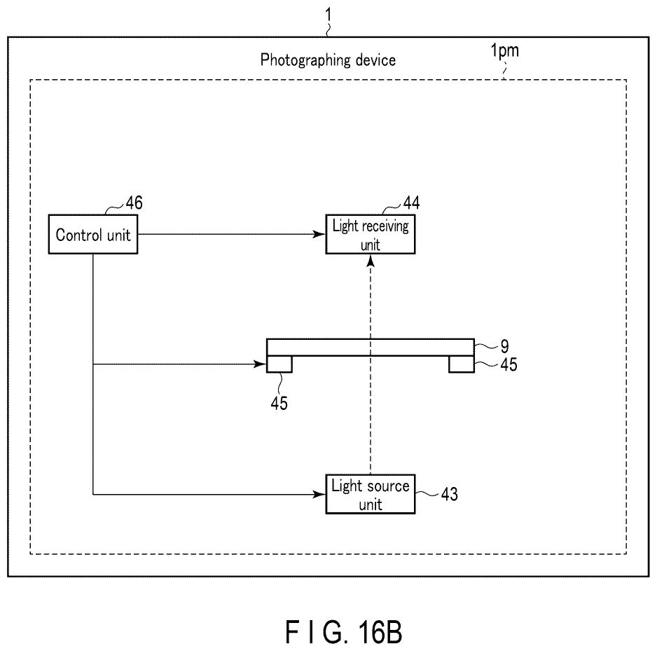

FIG. 16A is a block diagram showing a configuration example of a photographing device in the semiconductor inspection apparatus according to the second embodiment. The photographing device 1 includes an epi-illumination optical microscopy device 1pm, in place of the X-ray topography device 1xrt. The optical microscopy device 1pm includes a light source unit 41, a half mirror 42, a light receiving unit 44, a sample stage 45, and a control unit 46. The sample stage 45 holds a wafer 9 subjected to a chemical treatment by the etch pit method.

The light source unit 41 outputs light that has been generated in a light source and transmitted through a lens to the half mirror 42, where the light is refracted, and irradiates the refracted light onto the wafer 9 on the sample stage 45. The light reflected from the wafer 9 is transmitted through the half mirror 42 and is made incident on the light receiving unit 44. The light receiving unit 44 focuses the incident light with an objective lens, and detects the obtained transmission light with an image sensor, and outputs a result of the detection to the control unit 46.

Note that a transmitted-light microscopy device as shown in FIG. 16B may be used as the optical microscopy device 1pm. In this case, the optical microscopy device 1pm includes a light source unit 43, a light receiving unit 44, a sample stage 45, and a control unit 46. The light source unit 43 outputs parallel light that has been generated in a light source and transmitted through a condenser lens, and irradiates the parallel light onto the wafer 9 on the sample stage 45. The parallel light that has transmitted through the wafer 9 is made incident on the light receiving unit 44. The light receiving unit 44 focuses the incident light with an objective lens, and detects the obtained transmission light with an image sensor, and outputs a result of the detection to the control unit 46. However, in the present embodiment, a case of using an epi-illumination microscope, as shown in FIG. 16A, will be described as an example.

The control unit 46 is adapted to control the light source unit 41 (or 43), the light receiving unit 44, and the sample stage 45, under the control of the computer 2. The control unit 46 scans an entire region of the wafer 9 or a representative partial region in the wafer 9 through control of each unit. The control unit 46 generates, based on an output from the light receiving unit 44 related to a scanned region in the wafer 9, an optical image of the wafer 9. The optical image indicates results of defect inspection of the back surface and the top surface of the wafer 9. The X-ray topography images may be generated by the computer 2 which has received a result of detecting from the photographing device 1.

On the other hand, the acquiring function 211 of the processing circuitry 21 is adapted to acquire images of the wafer 9 by photographing the wafer 9 with the optical microscopy device 1pm. The photographing device 1 and the acquiring function 211 are examples of an acquiring unit. Herein, the acquiring unit includes an optical microscopy device 1pm adapted to photograph the wafer 9, thus allowing the acquiring function 211 to acquire images of the wafer 9.

Here, through etching by the etch pit method, the wafer 9 is brought to a state in which a first etch pit in a dot shape is formed on its back surface in correspondence with the threading dislocation 999, and a second etch pit in a hexagonal shape is formed on its top surface in correspondence with the threading dislocation 999. The first etch pit and the second etch pit are crystalline defects that have been revealed by chemical treatment according to the etch pit method. The hexagonal shape of the second etch pit represents a contour of the second etch pit that has occurred as a result of anisotropic etching. In accordance therewith, the optical image of the wafer 9 is an image representing the dot-shaped first etch pit and the hexagonal-shaped second etch pit formed in correspondence with the threading dislocation 999. That is, in the first embodiment, two X-ray topography images of the wafer 9, namely, an image representing a top surface and an image representing a back surface of the same scanning region, are generated. On the other hand, in the second embodiment, a single optical image of the wafer 9 representing the top and back surfaces of the same scanning region in a superimposed manner is generated. That is, the optical image of the wafer 9 is obtained by capturing the top and back views of the wafer 9 at corresponding coordinates into a single image.

The detecting function 212 detects a position of the first etch pit indicated by the image of the wafer 9 as a first coordinate point, and a position of the second etch pit indicated by the image as a second coordinate point. The detecting function 212 is adapted, for example, to detect a position of a midpoint of diagonal lines of the hexagonal shape as the second coordinate point, and a position of the dot shape as the first coordinate point. Note that the detecting function 212 may be adapted, if the first coordinate point is not detected and the second coordinate point is detected, to output a result of the detecting not including the first coordinate point but including the second coordinate point.

The analyzing function 213 is adapted, upon receiving the result of the detecting not including the first coordinate point but including the second coordinate point, to output, based on the result of the detecting, a result of analyzing not including an inclination θ of a dislocation line.

The classifying function 214 is adapted, if the result of the analyzing does not include the inclination θ of the dislocation line, to classify the threading dislocation of the dislocation line as lacking etching. Note that the managing function 215 may be adapted to adjust observation conditions such as a focal point of the optical microscopy device 1pm within a predetermined range based on a classifying result of lacking etching, and transmit a result of the adjustment to the control unit 46. The control unit 46 is adapted to control each component in accordance with the observation conditions.

The other configurations are similar to those of the first embodiment.

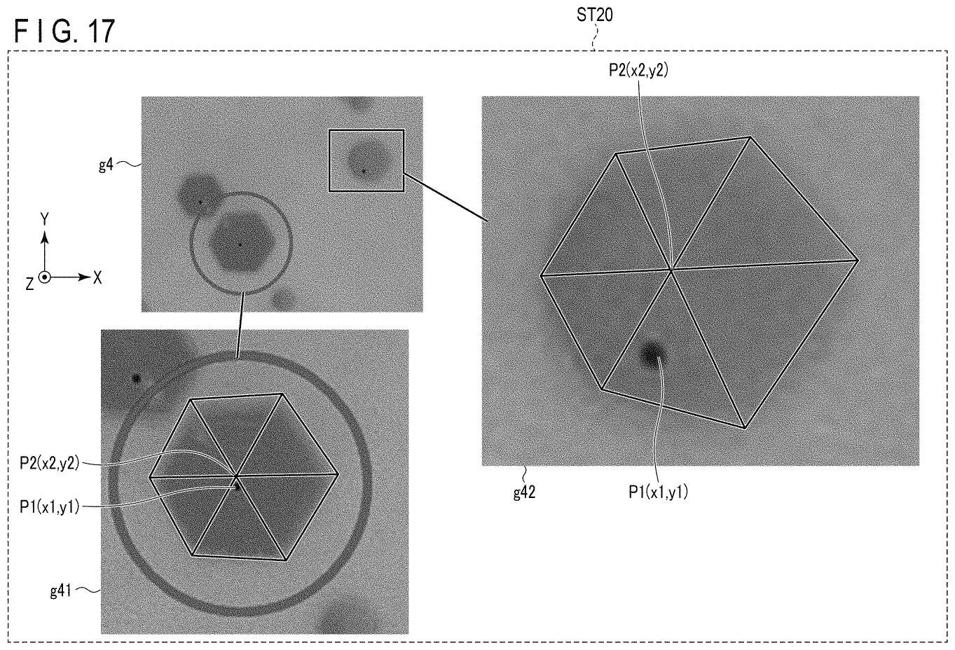

Next, an operation example of the semiconductor inspection apparatus 100 with the above-described configuration will be described with reference to the flowchart of FIG. 8 and the schematic diagrams of FIGS. 17-24. Hereinafter, a description will be made by omitting descriptions of overlapping portions.

### (Step ST10)

The photographing device 1 of the semiconductor inspection apparatus 100 scans an entire region or a representative partial region of the wafer 9 held on the sample stage 45 through control of the light source unit 41, the light receiving unit 44, and the sample stage 45 by the control unit 19. Note that the sample stage 45 continuously holds the wafer 9 until photographing of the wafer 9 is completed.

After the scanning, the control unit 46 generates images of the wafer 9 based on an output of the light receiving unit 44, and transmits the image to the computer 2. The processing circuitry 21 of the computer 2 acquires the image of the wafer 9.

### (Step ST20)

The processing circuitry 21 detects, based on the image acquired at step ST10, coordinates of a threading dislocation 999 on both surfaces of the wafer 9. For example, the processing circuitry 21 detects a position of a first etch pit indicated by an image g4 of the wafer 9 as a first coordinate point, and a position of a second etch pit indicated by the image g4 as a second coordinate point, as shown in FIG. 17. As an example, a single etch pit region in the image g4 is shown in an image g41 in an enlarged manner, and the other etch pit region is shown in an image g42 in an enlarged manner. For each of the images g41 and g42, the processing circuitry 21 detects a position of a midpoint of diagonal lines of the hexagonal shape as the second coordinate point P2(x2,y2), and a position of the dot shape as the first coordinate point P1(x1,y1). The first coordinate point and the second coordinate point are similarly detected for the other etch pits in the image g4. The processing circuitry 21 stores a result of the detecting at step ST20 as the wafer information 35 in the database 3.

### (Step St30)

The processing circuitry 21 analyzes, based on the result of the detecting at step ST20, an inclination and an extension orientation of a dislocation line of the threading dislocation in the wafer 9. For example, the processing circuitry 21 calculates a length L between the first coordinate point P1 (x1, y1) and the second coordinate point P2 (x2, y2) in an X-Y plane of the wafer 9, through the above-described formula (1).

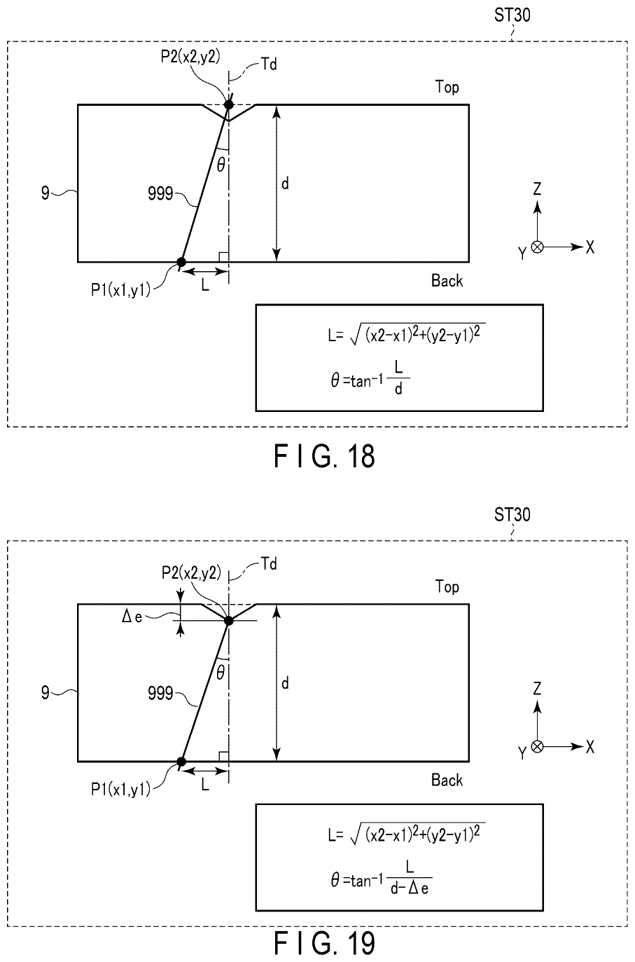

Similarly, the processing circuitry 21 calculates, based on the length L and a thickness d of the wafer 9, an inclination θ of a dislocation line of a threading dislocation 999 relative to a thickness direction Td of the wafer 9, through FIG. 18 and the formula (2).

That is, even if an etch pit is present on the top surface of the wafer 9, the inclination θ of the dislocation line is calculated based on the first coordinate point P1 (x1, y1), the second coordinate point P2 (x2, y2), and the thickness d of the wafer 9, similarly to the above, as shown in FIG. 18. The configuration is not limited thereto, and the inclination θ of the dislocation line may be derived based on a value (d−Δe) obtained by subtracting a depth Δe of the etch pit from the thickness d of the wafer 9, as shown in FIG. 19 and the formula (2a).

$$θ = tan \hat{} - 1 ( L / ( d - Δ e ) ) \qquad ( 2 a )$$

The depth Δe of the etch pit is a value obtained by multiplying the etching rate with an etching time.

Subsequently, the processing circuitry 21 analyzes an extension orientation of the threading dislocation 999, similarly to the above, based on the first coordinate point P1 (x1, y1) and the second coordinate point P2 (x2, y2). The processing circuitry 21 stores a result of the analyzing at step ST30 as the wafer information 35 in the database 3.

### (Step St40)

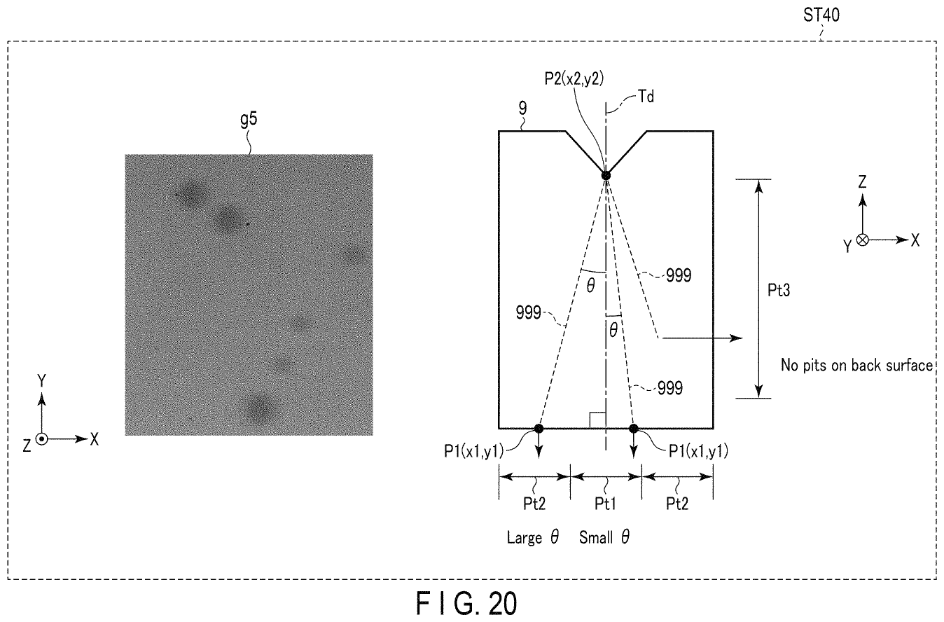

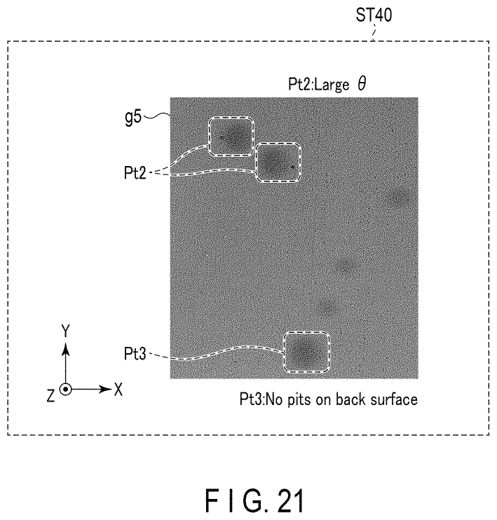

The processing circuitry 21 classifies the threading dislocation 999 in the wafer 9 based on a result of the analyzing at step ST30. For example, the processing circuitry 21 may classify the threading dislocation according to whether or not the inclination θ indicated by the result of the analyzing in the image g5 of the wafer 9 falls within a threshold range, as shown in FIGS. 20 and 21. In this case, the processing circuitry 21 classifies, among the threading dislocations 999, threading dislocations 999 with a small inclination θ into a specific pattern Pt1, and threading dislocations 999 with a large inclination θ into a specific pattern Pt2. Also, if a result of analyzing does not include an inclination θ of a dislocation line, the processing circuitry 21 classifies the threading dislocation of the dislocation line into a specific pattern Pt3, based on the result of the detecting not including the first coordinate point but including the second coordinate point. The specific pattern Pt3 is a pattern with no etch pits on the back surface, and indicates the lack of etching.

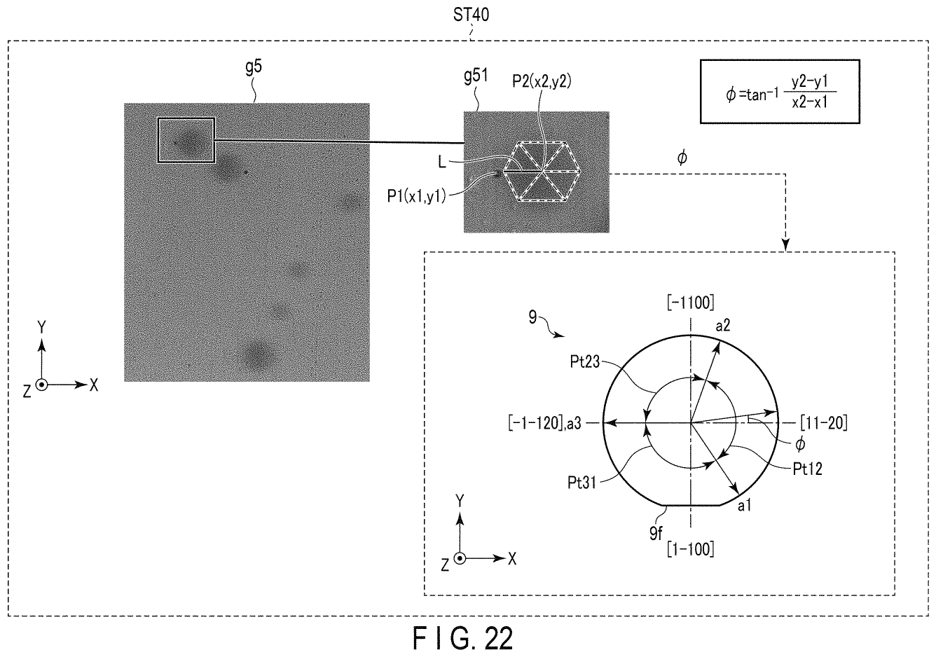

Moreover, the processing circuitry 21 may be adapted to further classify the threading dislocation 999 according to which of a plurality of orientation ranges an extension orientation indicated by a result of analyzing falls into. For example, the processing circuitry 21 derives, through the above-described formula (3), an angle φ of a threading dislocation traveling from the first coordinate point P1 (x1, y1) to the second coordinate point P2 (x2, y2) in an image g51, which is an enlarged view of a part of the image g5, as shown in FIG. 22. Also, since the extension orientation [11-20], which corresponds to the angle φ, falls within a range between the a1-axis direction and the a2-axis direction, the processing circuitry 21 classifies the threading dislocation into a specific pattern Pt12. Note that, if the extension orientation corresponding to the angle φ falls within a range between the a2-axis direction and the a3-axis direction, the processing circuitry 21 classifies the threading dislocation with the angle φ into a specific pattern Pt23. Similarly, if the extension orientation corresponding to the angle φ falls within a range between the a3-axis direction and the a1-axis direction, the processing circuitry 21 classifies the threading dislocation with the angle φ into a specific pattern Pt31.

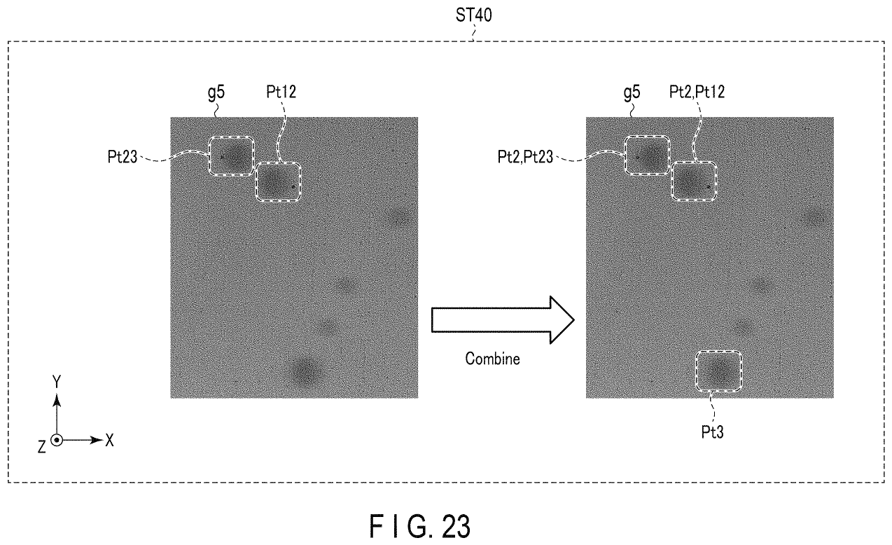

Moreover, the processing circuitry 21 may be adapted to combine the specific patterns Pt12 and Pt23 of the classifying results related to the extension orientation with the specific pattern Pt2 of the classifying result related to the inclination θ, as shown in FIG. 23.

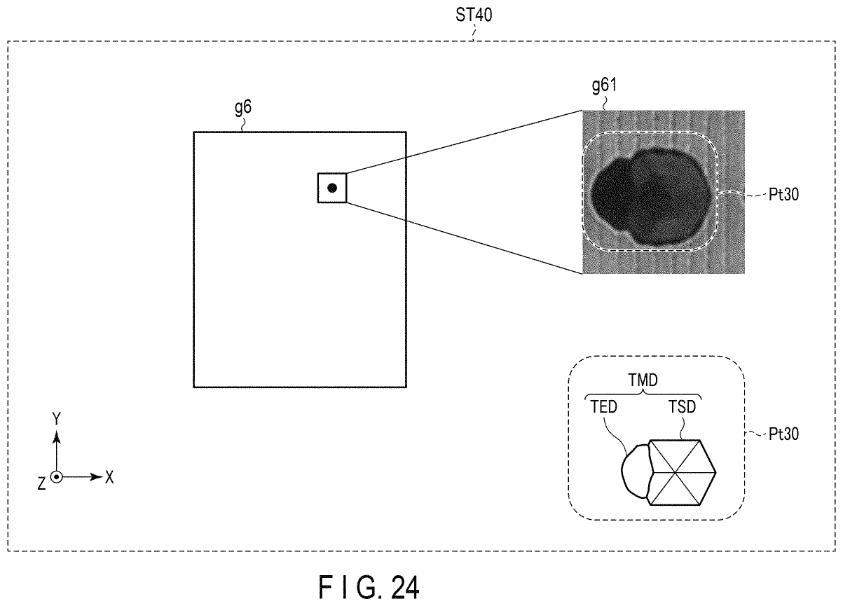

Furthermore, the processing circuitry 21 classifies, based on the images of the wafer 9, whether or not the threading dislocation 999 is a threading mixed dislocation. For example, the processing circuitry 21 determines that the threading dislocation in an image g61, which is an enlarged view of a part of the image g6, as shown in FIG. 24, is a threading mixed dislocation (TMD) of a threading edge dislocation (TED) and a threading screw dislocation (TSD), and classifies the threading dislocation into a specific pattern Pt30. Note that the etch pit shown in FIG. 24 has a contour shape in which a part of an approximately hexagonal shape and an approximately semicircular shape are mixed. Thereafter, the processing circuitry 21 further classifies the threading dislocation 999 by combining the result of classifying indicating the threading mixed dislocation and the result of classifying based on the result of the analyzing. Moreover, the processing circuitry 21 may be adapted to determine an abnormal area in the wafer 9 based on results of classifying of the threading dislocations 999 in the wafer 9. The processing circuitry 21 stores the results of the classifying at step ST40 as the wafer information 35 in the database 3.

### (Step ST50)

After step ST40, the processing circuitry 21 executes step ST50 similarly to the above, and ends the processing.

As described above, according to the second embodiment, through etching by the etch pit method, the wafer 9 is brought to a state in which a first etch pit in a dot shape is formed on its back surface in correspondence with the threading dislocation 999, and a second etch pit in a hexagonal shape is formed on its top surface in correspondence with the threading dislocation 999. The processing circuitry 21 detects a position of the first etch pit indicated by the image as a first coordinate point P1(x1, y1), and a position of the second etch pit indicated by the image as a second coordinate point P2(x2, y2). Accordingly, even in the case of using the etch pit method, it is possible, with the configuration of detecting the first coordinate point and the second coordinate point of the threading dislocation from an image of the wafer, to obtain similar advantageous effects as can be obtained by the first embodiment.

Moreover, according to the second embodiment, the processing circuitry 21 is adapted to detect a position of a midpoint of diagonal lines of the hexagonal shape as the second coordinate point, and a position of the dot shape as the first coordinate point. Accordingly, in the case of using the etch pit method, it is possible, with the configuration of detecting the second coordinate point of each etch pit by the same method, to reduce variation among the second coordinate points that are detected for the etch pits.

Also, according to the second embodiment, the processing circuitry 21 is configured, if the first coordinate point is not detected and the second coordinate point is detected, to output a result of the detecting not including the first coordinate point but including the second coordinate point. The processing circuitry 21 outputs a result of analyzing not including an inclination θ of a dislocation line, based on the result of the detecting. The processing circuitry 21 is adapted, if a result of analyzing does not include the inclination θ, to classify the threading dislocation as lacking etching. Accordingly, it is possible to detect insufficient etching in the event of the lack of etching in the etch pit method.

Moreover, according to the second embodiment, the acquiring unit including the photographing device 1 and the acquiring function 211 may include an optical microscopy device 1pm adapted to photograph the wafer 9, thereby acquiring images g4, g5 and g6 of the wafer 9. In this case, it is possible to photograph and acquire images of a wafer using an optical microscopy device, among given photographing devices capable of photographing a wafer.

### Modification of Second Embodiment

In the second embodiment, the etch pit method and the optical microscopy device 1pm have been used; however, the configuration is not limited thereto. For example, the second embodiment may be modified to a configuration that uses, in addition to the etch pit method, an X-ray topography device 1xrt in place of the optical microscopy device 1pm. The other configurations are similar to those of the second embodiment. In this case, the processing circuitry 21 detects a position of a midpoint of diagonal lines of a hexagonal shape as the second coordinate point, based on an image of the surface of the wafer 9. Also, the processing circuitry 21 detects a position of the dot shape as the first coordinate point, based on the back-surface image of the wafer 9. Even with such a modification, it is possible to obtain similar effects as can be obtained by the second embodiment. Similarly, if the first coordinate point is not detected but the second coordinate point is detected, the processing circuitry 21 is adapted, based on the result of the detecting, to output a result of analyzing not including an inclination θ of a dislocation line, and to classify the threading dislocation as lacking etching. Accordingly, it is possible to detect a lack of etching by the etch pit method, similarly to the above-described configuration.

According to at least one embodiment described above, it is possible to grasp inclinations of dislocation lines in a wafer over a wide range. The same applies to the at least one modification described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor inspection apparatus, comprising:
processing circuitry configured to:
acquire an image of a wafer by photographing the wafer with a photographing device;
detect, based on the image, a first coordinate point of a threading dislocation that has appeared on a back surface of the wafer and a second coordinate point of the threading dislocation that has appeared on a top surface of the wafer;
analyze, based on the first coordinate point and the second coordinate point and a thickness of the wafer, an inclination of a dislocation line of the threading dislocation relative to a thickness direction of the wafer; and
classify the threading dislocation based on a result of the analyzing.

2. The semiconductor inspection apparatus according to claim 1, wherein
the processing circuitry is configured to classify the threading dislocation according to whether or not the inclination indicated by the result of the analyzing falls within a threshold range.

3. The semiconductor inspection apparatus according to claim 1, wherein
the processing circuitry is configured to further analyze an extension orientation of the dislocation line based on the first coordinate point and the second coordinate point.

4. The semiconductor inspection apparatus according to claim 3, wherein
the processing circuitry is configured to further classify the threading dislocation according to which of a plurality of orientation ranges the extension orientation indicated by the result of the analyzing falls into.

5. The semiconductor inspection apparatus according to claim 3, wherein
the processing circuitry is configured to classify, based on the image, whether or not the threading dislocation is a threading mixed dislocation, and to further classify the threading dislocation by combining a result of the classifying indicating the threading mixed dislocation and a result of the classifying based on the result of the analyzing.

6. The semiconductor inspection apparatus according to claim 3, wherein
the processing circuitry is configured to determine an abnormal area in the wafer based on results of classifying of a plurality of threading dislocations in the wafer.

7. The semiconductor inspection apparatus according to claim 3, wherein
the processing circuitry is configured to predict, based on the first coordinate point and the second coordinate point and the extension orientation of the dislocation line, a third coordinate point of the threading dislocation that would appear on a back surface of another wafer different from the wafer, and a fourth coordinate point of the threading dislocation that would appear on a top surface of said another wafer, said another wafer and the wafer having been cut from a same ingot.

8. The semiconductor inspection apparatus according to claim 7, wherein
the processing circuitry is configured to classify the threading dislocation including the third coordinate point and the fourth coordinate point in accordance with a result of the classifying of the threading dislocation including the first coordinate point and the second coordinate point.

9. The semiconductor inspection apparatus according to claim 1, wherein
the processing circuitry is configured to:
acquire an image of the back surface of the wafer and an image of the top surface of the wafer by photographing, with the photographing device, both the back surface and the top surface of the wafer while continuously holding the wafer; and
detect the first coordinate point based on the image of the back surface, and detect the second coordinate point based on the image of the top surface.

10. The semiconductor inspection apparatus according to claim 1, wherein
the wafer is, through etching by an etch pit method, brought to a state in which a first etch pit in a dot shape is formed on the back surface in correspondence with the threading dislocation, and a second etch pit in a hexagonal shape is formed on the top surface in correspondence with the threading dislocation, and
the processing circuitry is configured to detect a position of the first etch pit indicated by the image as the first coordinate point, and a position of the second etch pit indicated by the image as the second coordinate point.

11. The semiconductor inspection apparatus according to claim 10, wherein
the processing circuitry is configured to detect a position of a midpoint of diagonal lines of the hexagonal shape as the second coordinate point, and a position of the dot shape as the first coordinate point.

12. The semiconductor inspection apparatus according to claim 10, wherein
the processing circuitry is configured to:
output, if the first coordinate point is not detected but the second coordinate point is detected, a result of the detecting not including the first coordinate point but including the second coordinate point;
output, based on the result of the detecting, a result of analyzing not including the inclination; and
classify, if the result of the analyzing does not include the inclination, the threading dislocation as lacking etching.

13. The semiconductor inspection apparatus according to claim 9, wherein
the photographing device includes an X-ray topography device, and
the processing circuitry is configured to acquire the images of the wafer by causing the X-ray topography device to photograph the wafer.

14. The semiconductor inspection apparatus according to claim 10, wherein
the photographing device includes an optical microscope, and
the processing circuitry is configured to acquire the image of the wafer by causing the optical microscope to photograph the wafer.

15. An inspection method executed by a semiconductor inspection apparatus, the method comprising:
acquiring an image of a wafer by photographing the wafer with a photographing device;
detecting, based on the image, a first coordinate point of a threading dislocation that has appeared on a back surface of the wafer and a second coordinate point of the threading dislocation that has appeared on a top surface of the wafer;
analyzing, based on the first coordinate point and the second coordinate point and a thickness of the wafer, an inclination of a dislocation line of the threading dislocation relative to a thickness direction of the wafer; and
classifying the threading dislocation based on a result of the analyzing.
